(19) United States
(12) Patent Application Publication
(10) Pub. No.: US 2019/0287931 A1
(43) Pub. Date: Sep. 19, 2019

(54) CHIP ON FILM PACKAGE

(71) Applicant: Novatek Microelectronics Corp., Hsinchu (TW)

(72) Inventors: Chien-Chen Ko, Hsinchu City (TW); Chiao-Ling Huang, Hsinchu City (TW)

(73) Assignee: Novatek Microelectronics Corp., Hsinchu (TW)

(21) Appl. No.: 15/922,832

(22) Filed: Mar. 15, 2018

(51) Int. Cl. H01L 23/00; H01L 23/29; H01L 23/31; H01L 21/48; H01L 21/56

(52) U.S. Cl. CPC H01L 23/564; H01L 23/295; H01L 21/563; H01L 21/48; H01L 23/3114

(57) ABSTRACT

A chip on film package including a base film, a patterned circuit layer, a chip, an underfill portion, and a water resistant layer. The base film includes a first surface and a second surface opposite to the first surface, and the first surface includes a mounting region. The patterned circuit layer is disposed on the first surface. The chip is mounted on the mounting region and electrically connected to the patterned circuit layer. The underfill portion covers a connecting portion where the chip and the pattern circuit layer are connected. The water resistant layer at least coves an outer surface of the underfill, wherein the material of the water resistant layer includes resin and metal particles.

### BACKGROUND OF THE INVENTION

### Field of the Invention

The present disclosure generally relates to a chip package. More particularly, the present disclosure relates to a chip on film package.

### Description of Related Art

To expand the market area of display devices such as liquid crystal displays (LCDs), with promotion of low cost, large scale, and high performance, more pixels have to be integrated in a small area. Thus, as a lead pitch of a driver integrated circuit (IC) which controls each pixel becomes finer within the display device, various packaging methods have been developed.

Packaging methods mainly used in a display device field include a tape carrier packaging (TCP) method, a chip on glass (COG) packaging method, a chip on film (COF) packaging method, and the like. These methods are referred to as wireless methods. To promote reduction in fabrication cost and improvement in yield due to a fine pitch, the share of COF technology in the packaging market has gradually increased since the late 1990s.

Since COF technology uses a base film on which fine wiring patterns are formed, the distance and pitch between neighboring leads can be minimized, thus maximizing lead density. Further, this COF technology can employ semiconductor chips with a large number of chip pads and fine pitch or large-sized semiconductor chips. Therefore, the COF technology using the base film achieves high-integrated and multi-functional semiconductor device.

The COF package has an excellent bending force and a good flexibility, compared to the conventional chip package, is of high quality. However, as the demand for the IC packages of higher performances increases, inner leads/outer leads of COF package are required not only to be increased in number but also to be more fine pitch. As a result, the requirements of resisting humidity and mechanical external force for COF packages have become more and more strict and harder to comply.

### SUMMARY OF THE INVENTION

Accordingly, the present disclosure is directed to a chip on film package with favorable resistance to humidity and mechanical external force.

The present disclosure is directed to a chip on film package including a base film, a patterned circuit layer, a chip, an underfill portion, and a water resistant layer. The base film includes a first surface and a second surface opposite to the first surface, wherein the first surface includes a mounting region located on the first surface. The patterned circuit layer is disposed on the first surface. The chip is mounted on the mounting region and electrically connected to the patterned circuit layer. The chip includes an active surface facing the first surface of the base film, a back surface opposite to the active surface, and a plurality of side surfaces connected between the active surface and the back surface. The underfill portion covers a connecting portion where the chip and the pattern circuit layer are connected and a first region of the plurality of side surfaces of the chip. The water resistant layer at least covers a second region of the plurality of side surfaces of the chip and covering an outer surface of the underfill portion. The second region connects the first region and the material of the water resistant layer includes resin and metal particles.

The present disclosure provides a manufacturing method of a chip on film package. The method includes the following steps. A base film is provided, wherein the base film includes a first surface including a mounting region, and a second surface opposite to the first surface. A patterned circuit layer is formed on the first surface. A chip is mounted on the mounting region, wherein the chip is electrically connected to the patterned circuit layer and includes an active surface facing the first surface of the base film, a back surface opposite to the active surface, and a plurality of side surfaces connected between the active surface and the back surface. An underfill portion is formed, wherein the underfill portion covers a connecting portion where the chip and the pattern circuit layer are connected and covers a first region of the plurality of side surfaces of the chip. A water resistant layer is formed on the underfill portion, wherein the water resistant layer at least covers a second region of the plurality of side surfaces of the chip and covers an outer surface of the underfill portion, the second region connects the first region, and the material of the water resistant layer includes resin and metal particles.

According to an embodiment of the present invention, the water resistant layer further covers the back surface of the chip.

According to an embodiment of the present invention, the resin includes epoxy.

According to an embodiment of the present invention, the metal particles includes aluminum particles or copper particles.

According to an embodiment of the present invention, the chip on film package further includes a solder resist layer disposed on the patterned circuit layer, and the water resistant layer further covers a part of the solder resist layer.

According to an embodiment of the present invention, the chip on film package further includes a back water resistant layer disposed on the second surface and being overlapping with the mounting region along a normal direction of the second surface.

According to an embodiment of the present invention, the second region is connected to the back surface.

According to an embodiment of the present invention, the manufacturing method of the chip on film package further includes performing a curing process on the water resistant layer.

According to an embodiment of the present invention, the manufacturing method of the chip on film package further includes forming a solder resist layer on the patterned circuit layer before the water resistant layer is formed on the underfill portion, wherein the water resistant layer covers a part of the solder resist layer.

According to an embodiment of the present invention, the underfill portion is formed after the solder resist layer is formed.

According to an embodiment of the present invention, the manufacturing method of the chip on film package further includes forming a back water resistant layer on the second surface.

According to an embodiment of the present invention, the back water resistant layer is overlapping with the mounting region along a normal direction of the second surface.

According to an embodiment of the present invention, the water resistant layer further covers the back surface of the chip.

In light of the foregoing, in the chip on film package of the disclosure, a water resistant layer is formed to cover the underfill portion of the package. The material of the water resistant layer includes resin and metal particles. Accordingly, the water resistant layer have great water resistance and mechanical strength, so as to enhance the protection of electronic parts of the chip on film package from temperature, humidity, and mechanical external force, etc. In addition, the metal particles in the water resistant layer provides great heat conductivity to improve the heat dissipation of the chip on film package. Therefore, the chip on film package of the disclosure can have higher yield rate, stronger mechanical strength and better heat dissipation.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 to FIG. 5 illustrate cross-section views of a chip on film package in a manufacturing process according to an embodiment of the disclosure.

FIG. 5A illustrates a cross-section view of a chip on film package according to an embodiment of the disclosure.

FIG. 6 illustrates a cross-section view of a chip on film package according to an embodiment of the disclosure.

FIG. 7 illustrates a cross-section view of a chip on film package according to an embodiment of the disclosure.

FIG. 8 illustrates a cross-section view of a chip on film package according to an embodiment of the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

The present disclosure will now be described more fully with reference to the accompanying drawings, in which exemplary embodiments of the disclosure are shown. The terms used herein such as “above”, “below”, “front”, “back”, “left” and “right” are for the purpose of describing directions in the figures only and are not intended to be limiting of the disclosure. Moreover, in the following embodiments, the same or similar reference numbers denote the same or like components.

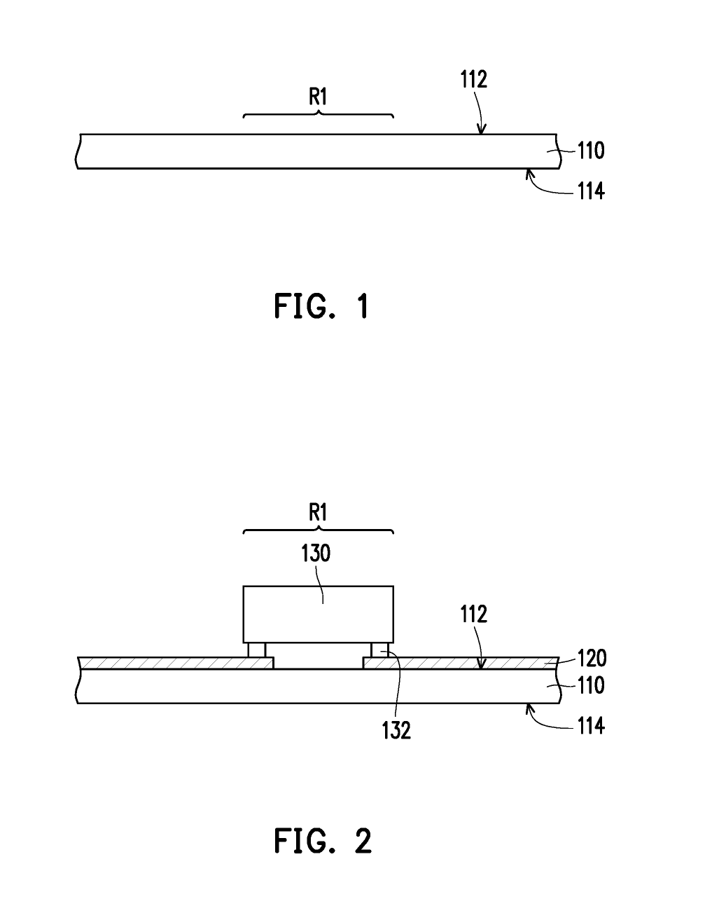

FIG. 1 to FIG. 5 illustrate cross-section views of a chip on film package in a manufacturing process according to an embodiment of the disclosure. In some embodiments, a manufacturing process of a chip on film package may include the following steps. Referring to FIG. 1, a base film 110 is provided. In the present embodiment, the base film 110 may be formed of a resin-based material (e.g., polyimide or polyester), but the disclosure is not limited thereto. Accordingly, the base film 110 may have flexibility. In the present embodiment, the base film 110 includes a first surface 112 and a second surface 114. The second surface 114 is opposite to the first surface 112, and the first surface 112 includes a mounting region R1.

Referring to FIG. 2, a patterned circuit layer 120 is formed on the first surface 112 of the base film 110. Even through not shown in detail in the drawings, the patterned circuit layer 120 may include metal wires having conductivity and the two ends of each wire may be respectively an inner lead connecting to the chip 130 and an outer lead which is for connecting to an external device (such as a display panel or a printed circuit board). For example, the patterned circuit layer 120 may include copper (Cu). In some embodiments, the patterned circuit layer 120 may be formed by electroplating and etching process, etc. The wires except the inner leads and the outer leads may be covered and protected by insulating layers such as a solder resist layer 140 shown in FIG. 3.

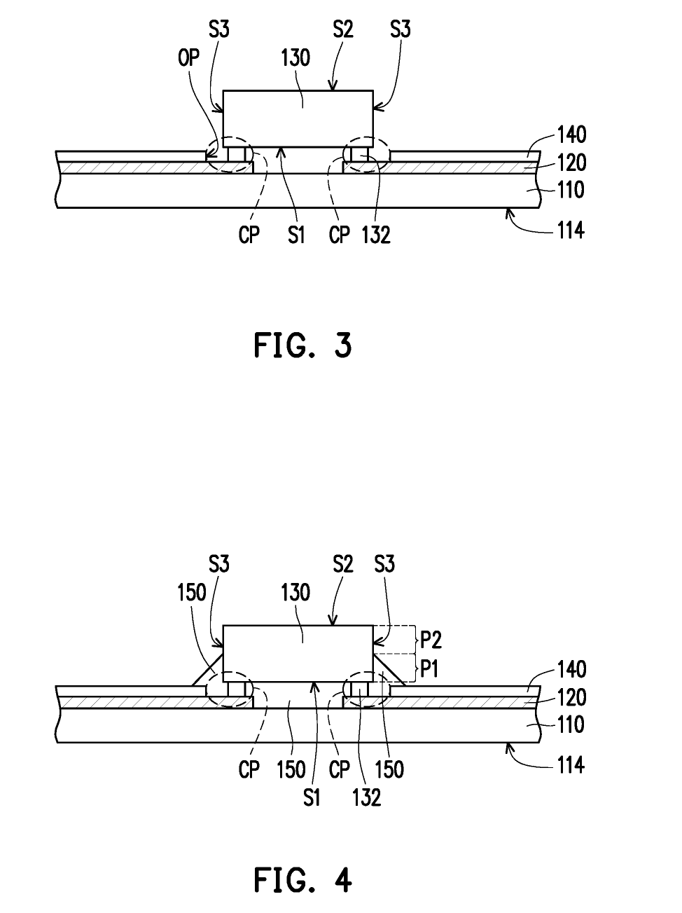

Referring to FIG. 2 and FIG. 3, a chip 130 may be mounted on the mounting region R1. In the present embodiments, the chip 130 is electrically connected to the patterned circuit layer 120 by, for example, flip chip bonding or other suitable bonding techniques. The chip 130 includes an active surface S1 facing the first surface 112 of the base film 110, a back surface S2 opposite to the active surface S1, and a plurality of side surfaces S3 connected between the active surface S1 and the back surface S2. In some embodiments, the chip 130 may be mounted on the mounting region R1 of the base film 110 through a plurality of conductive bumps 132. In detail, the chip 130 is connected to the inner leads of the patterned circuit layer 120 through the conductive bumps 132. In some embodiments, a solder resist layer 140 may be formed on the patterned circuit layer 120. It is noted that the solder resist layer 140 may be formed before the chip 130 is mounted on the mounting region R1, or formed after the chip 130 is mounted on the mounting region R1 but before the water resistant layer 160 shown in FIG. 5 is formed. After the solder resist layer 140 is formed, it can be seen that a connecting portion CP where the chip 130 and the pattern circuit layer 120 are connected is exposed. In some embodiment, the connecting portion CP includes a part of the patterned circuit layer 120 (i.e., inner leads) and side surfaces of the conductive bumps 132 (if any). After the chip 130 is mounted and the solder resist layer 140 is formed, outward ends of the inner leads may be exposed.

Referring to FIG. 4, an underfill portion 150 is formed between the chip 130 and the base film 110 and covers the connecting portion CP where the chip 130 and the pattern circuit layer 120 are connected. The underfill portion 150 is configured for isolating moisture from external environment. The material of the underfill portion 150 is electrically non-conductive and may be resin, such as epoxy. Additionally, the underfill portion 150 may enhance the rigidity of the connecting portion CP. In some embodiments, the underfill portion 150 covers the first region P1, the part (e.g. inner leads) of the patterned circuit layer 120, and the side surfaces of the conductive bumps 132; the other region of the side surfaces S3 which connects to the first region P1, named a second region P2, is not covered by the underfill portion 150. In the process of forming the underfill portion 150, the underfill portion 150 also fills a space enclosed by the active surface S1 of the chip 130, the conductive bumps 132, and the first surface 112 of the base film 110. In some embodiments, the underfill portion 150 may be formed after the solder resist layer 140 is formed, such that the underfill portion 150 may cover a part of the solder resist layer 140, but the disclosure is not limited thereto.

Referring to FIG. 5, a water resistant layer 160 is formed on the underfill portion 150. In some embodiments, the water resistant layer 160 covers the underfill portion 150 completely. In the present embodiment, the water resistant layer 160 at least covers the second region P2 of the side surfaces S3 of the chip 130, an outer surface of the underfill portion 150, and a part of the solder resist layer 140.

In the present embodiment of FIG. 5, a topmost edge of the outer surface of the water resistant layer 160 may be ideally substantially same high as the back surface S2 of the chip 130 in view of the cross-section view (or a side view). Certainly, the disclosure is not limited thereto. In other embodiments, when an actual (non-ideal) manufacturing process is performed, the topmost edge of the outer surface of the water resistant layer 160 may be slightly higher than the back surface S2 of the chip 130, or slightly lower than the back surface S2 of the chip 130 such as the illustrated in a chip on film package 100′ in FIG. 5A, in view of the cross-section view. In FIG. 5A, the water resistant layer 160 covers the outer surface of the underfill portion 150 and exposes the topmost region of the side surfaces S3. In some embodiments, the water resistant layer 160 may be provided to cover the underfill portion 150 by dispensing, coating, or other suitable manner. Then, a curing process may be performed to cure the water resistant layer 160. The curing process may include baking or other suitable curing method. At the time, the manufacturing process of the chip on film package 100 may be substantially done.

The material of the water resistant layer 160 may include resin and metal particles. In some embodiments, the resin may include epoxy or other suitable material with great water resistance characteristic. The metal particles may include aluminum particles, copper particles, or other suitable material with great thermal conductivity. The thickness of the water resistant layer 160 may not be completely uniform and even, and the disclosure does not limit the disposition of the water resistant layer 160 as long as the water resistant layer 160 cover the outer surface of the underfill portion 150 to prevent the water, moisture from getting in. Accordingly, the water resistant layer 160 have great water resistance and mechanical strength, so as to enhance the protection of electronic parts (e.g. bonding pads of the chip 130, the inner leads of the patterned circuit layer 120 and the conductive bumps 132, etc.) of the chip on film package 100 from temperature, humidity, and mechanical external force, etc. In some embodiments, the water resistance capability of the water resistant layer 160 is greater than that of the underfill portion 150. In addition, the metal particles in the water resistant layer 160 provides great heat conductivity, so as to improve the heat dissipation of the chip on film package 100. In some embodiments, other heat dissipation component may be omitted and be replaced by the water resistant layer 160.

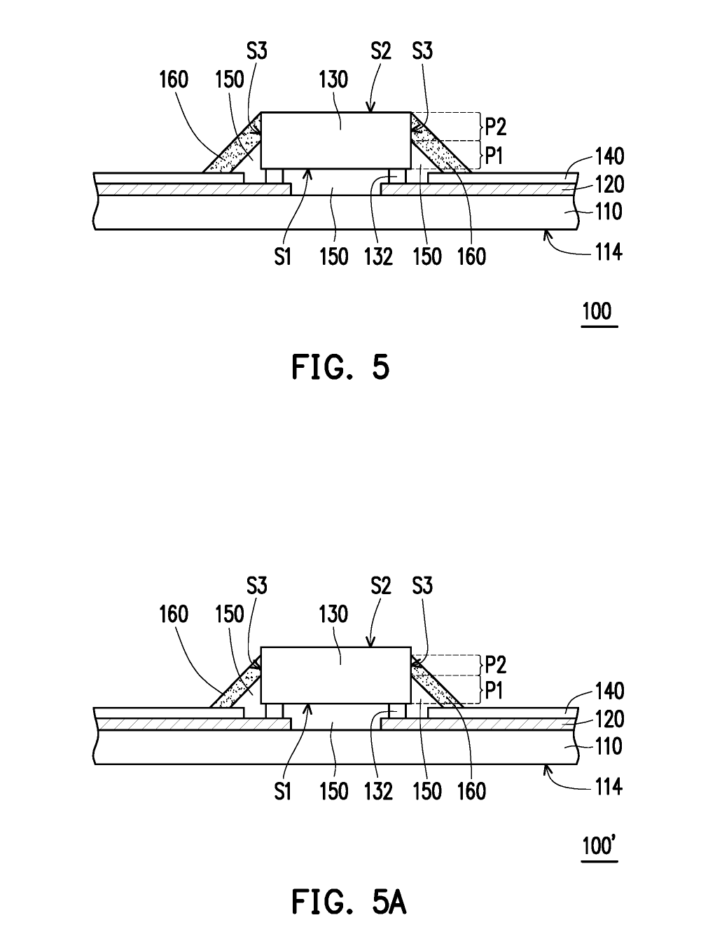

FIG. 6 illustrates a cross-section view of a chip on film package 100a according to an embodiment of the disclosure. It is noted that the chip on film package 100a shown in FIG. 6 contains many features same as or similar to the chip on film package 100 disclosed earlier with FIG. 1 to FIG. 5. For purpose of clarity and simplicity, detail description of same or similar features may be omitted, and the same or similar reference numbers denote the same or like components. The main differences between the chip on film package 100a shown in FIG. 6 and the chip on film package 100 shown in FIG. 5 are described hereinafter.

Referring to FIG. 6, in the present embodiment, the chip on film package 100a further includes a back water resistant layer 170, which is disposed on the second surface 114 of the base film 110. In some embodiments, the back water resistant layer 170 at least partially overlaps with the mounting region R1 along a normal direction N1 of the second surface 114. The material of the back water resistant layer 170 may be substantially the same as that of the water resistant layer 160, which includes resin and metal particles. Therefore, the back water resistant layer 170 can further prevent water or moisture from infiltrating through the second surface 114 of the base film 110 to further protect electronic parts of the chip on film package 100a. In addition, the metal particles in the back water resistant layer provides great heat conductivity, so as to further facilitate the heat dissipation of the chip on film package.

In some embodiments, the back water resistant layer 170 may be provided to cover a part of the second surface 114 of the base film 110 by the same method as the water resistant layer 160 is provided to cover the underfill portion 150 thereby, such as dispensing, coating, etc. Then, a curing process may also be performed on the back water resistant layer 170. The curing process may include baking or other suitable curing method. It is noted that the water resistant layer 160 and the back water resistant layer 170 may be formed separately or formed at the same step.

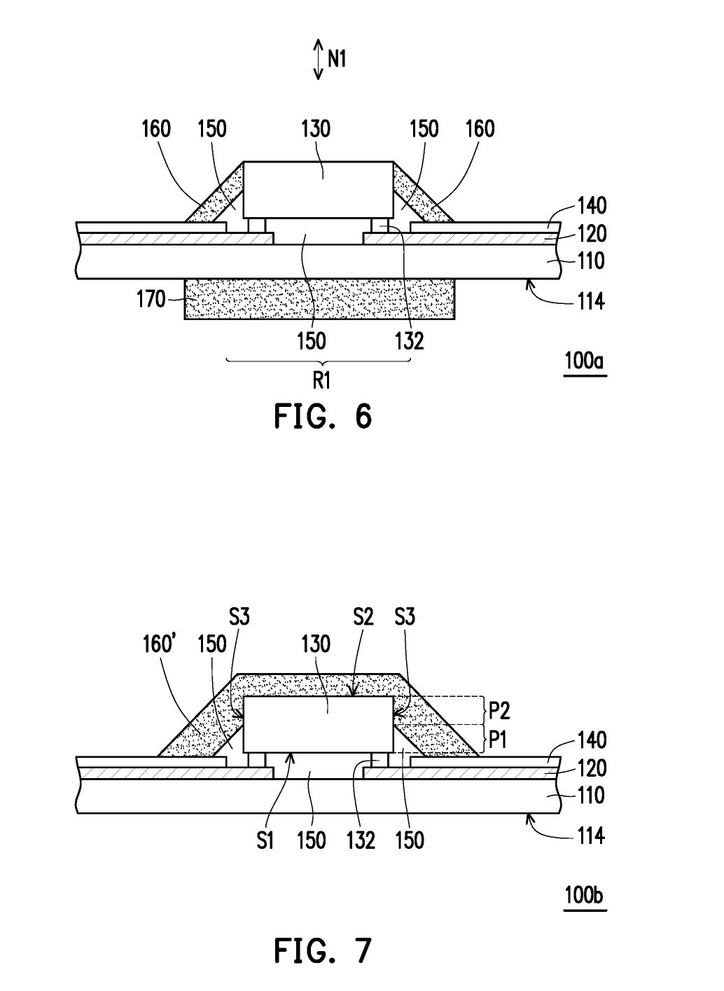

FIG. 7 illustrates a cross-section view of a chip on film package 100b according to an embodiment of the disclosure. It is noted that the chip on film package 100b shown in FIG. 7 contains many features same as or similar to the chip on film package 100 disclosed earlier with FIG. 1 to FIG. 5. For purpose of clarity and simplicity, detail description of same or similar features may be omitted, and the same or similar reference numbers denote the same or like components. The main differences between the chip on film package 100b shown in FIG. 7 and the chip on film package 100 shown in FIG. 5 are described hereinafter.

Referring to FIG. 7, in the present embodiment, a water resistant layer 160′ further covers the back surface S2 of the chip 130. That is, the water resistant layer 160′ covers the outer surface of the underfill portion 150, covers the second region P2 of the side surfaces S3, and further covers the back surface S2 of the chip 130. The water resistant layer 160′ can be dispensed or coated more easily to cover the underfill portion 150 and the chip 130.

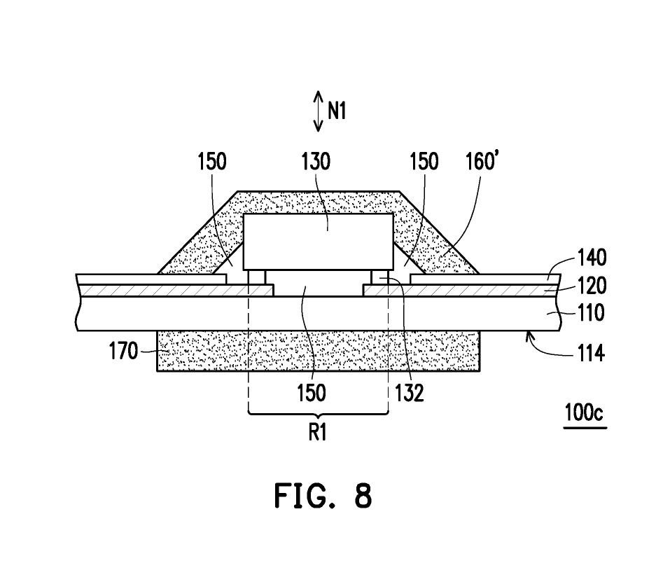

FIG. 8 illustrates a cross-section view of a chip on film package 100c according to an embodiment of the disclosure. It is noted that the chip on film package 100c shown in FIG. 8 contains many features same as or similar to the chip on film package 100b disclosed earlier with FIG. 7. For purpose of clarity and simplicity, detail description of same or similar features may be omitted, and the same or similar reference numbers denote the same or like components. The main differences between the chip on film package 100c shown in FIG. 8 and the chip on film package 100b shown in FIG. 7 are described hereinafter.

Referring to FIG. 8, in the present embodiment, the chip on film package 100c further includes a back water resistant layer 170, which is disposed on the second surface 114 of the base film 110. In some embodiments, the back water resistant layer 170 at least partially overlaps with the mounting region R1 along a normal direction N1 of the second surface 114. The material of the back water resistant layer 170 may be substantially the same as that of the water resistant layer 160′, which includes resin and metal particles. Therefore, the back water resistant layer 170 can further prevent water or moisture from infiltrating through the second surface 114 of the base film 110 to further protect electronic parts of the chip on film package 100c. In some embodiments, the back water resistant layer 170 may be provided to cover a part of the second surface 114 of the base film 110by the same method as the water resistant layer 160′ is provided thereby, such as dispensing, coating, etc. Then, a curing process may also be performed on the back water resistant layer 170. The curing process may include baking or other suitable curing method. It is noted that the water resistant layer 160′ and the back water resistant layer 170 may be formed separately or formed at the same step.

Based on the above discussions, it can be seen that the present disclosure offers various advantages. It is understood, however, that not all advantages are necessarily discussed herein, and other embodiments may offer different advantages, and that no particular advantage is required for all embodiments.

In sum, in the chip on film package of the disclosure, a water resistant layer is formed to cover the underfill portion of the chip on film package. The material of the water resistant layer includes resin and metal particles. Accordingly, the water resistant layer have great water resistance and mechanical strength, so as to further enhance the protection of electronic parts of the chip on film package from temperature, humidity, and mechanical external force, etc. In addition, the metal particles in the water resistant layer provides great heat conductivity, so as to improve the heat dissipation of the chip on film package. Therefore, the chip on film package of the disclosure can have higher yield rate, stronger mechanical strength and better heat dissipation.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

1. A chip on film package, comprising:
a base film being flexible and bendable, and comprising a first surface and a second surface opposite to the first surface, wherein the first surface comprises a mounting region;
a patterned circuit layer disposed on the first surface;
a chip mounted on the mounting region and electrically connected to the patterned circuit layer, wherein the chip comprising an active surface facing the first surface of the base film, a back surface opposite to the active surface, and a plurality of side surfaces connected between the active surface and the back surface;
an underfill portion, covering a connecting portion where the chip and the pattern circuit layer are connected and a first region of the plurality of side surfaces of the chip; and
a water resistant layer at least covering a second region of the plurality of side surfaces of the chip and covering an outer surface of the underfill portion, wherein the second region connects the first region and the material of the water resistant layer comprises resin and metal particles.

2. The chip on film package according to claim 1, wherein the water resistant layer further covers the back surface of the chip.

3. The chip on film package according to claim 1, wherein the resin comprises epoxy.

4. The chip on film package according to claim 1, wherein the metal particles comprises aluminum particles or copper particles.

5. The chip on film package according to claim 1, further comprising a solder resist layer disposed on the patterned circuit layer, and the water resistant layer further covers a part of the solder resist layer.

6. The chip on film package according to claim 1, further comprising a back water resistant layer disposed on the second surface and being overlapping with the mounting region along a normal direction of the second surface.

7. The chip on film package according to claim 1, wherein the second region is connected to the back surface.

8. A manufacturing method of a chip on film package, comprising:
providing a base film, wherein the base film is flexible and bendable, and comprises a first surface comprising a mounting region and a second surface opposite to the first surface;
forming a patterned circuit layer on the first surface;
mounting a chip on the mounting region, wherein the chip is electrically connected to the patterned circuit layer and comprises an active surface facing the first surface of the base film, a back surface opposite to the active surface, and a plurality of side surfaces connected between the active surface and the back surface; and
forming an underfill portion, wherein the underfill portion covers a connecting portion where the chip and the pattern circuit layer are connected and covers a first region of the plurality of side surfaces of the chip; and
forming a water resistant layer on the underfill portion, wherein the water resistant layer at least covers a second region of the plurality of side surfaces of the chip and covers an outer surface of the underfill portion, the second region connects the first region, and the material of the water resistant layer comprises resin and metal particles.

9. The manufacturing method of the chip on film package according to claim 8, further comprising:
performing a curing process on the water resistant layer.

10. The manufacturing method of the chip on film package according to claim 8, further comprising:
forming a solder resist layer on the patterned circuit layer before the water resistant layer is formed on the underfill portion, wherein the water resistant layer covers a part of the solder resist layer.

11. The manufacturing method of the chip on film package according to claim 10, wherein the underfill portion is formed after the solder resist layer s formed.

12. The manufacturing method of the chip on film package according to claim 8, further comprising:
forming a back water resistant layer on the second surface.

13. The manufacturing method of the chip on film package according to claim 12, wherein the back water resistant layer is overlapping with the mounting region along a normal direction of the second surface.

14. The manufacturing method of the chip on film package according to claim 8, wherein the water resistant layer further covers the back surface of the chip.

15. The chip on film package according to claim 1, wherein the water resistant layer exposes at least a periphery of the first surface of the base film.

16. The manufacturing method of the chip on film package according to claim 8, wherein the water resistant layer exposes at least a periphery of the first surface of the base film.
